(19) United States
(12) Patent Application Publication
(10) Pub. No.: US 2019/0131136 A1
(43) Pub. Date: May 2, 2019

(54) PLASMA PROCESSING APPARATUS

(71) Applicant: TOKYO ELECTRON LIMITED, Tokyo (JP)

(72) Inventors: Yuki HOSAKA, Miyagi (JP); Yoshihiro UMEZAWA, Miyagi (JP); Toshiki NAKAJIMA, Miyagi (JP); Mayo UDA, Miyagi (JP)

(73) Assignee: TOKYO ELECTRON LIMITED, Tokyo (JP)

(21) Appl. No.: 16/061,434

(22) PCT Filed: Dec. 2, 2016
(86) PCT No.: PCT/JP2016/085873

§ 371 Date: Jun. 12, 2018

(30) Foreign Application Priority Data
Dec. 16, 2015 (JP) 2015-245450

(51) Int. Cl. H01L 21/3065; H01J 37/32; H05H 1/46

(52) U.S. Cl. CPC H01L 21/3065; H05H 1/46; H01J 37/32816; H01J 37/32633

(57) ABSTRACT

A plasma processing apparatus includes a baffle plate, a shutter, and a driving device. The baffle plate has a cylindrical shape, and has a plurality of through holes formed in a sidewall thereof. The shutter has a cylindrical shape and is provided around the baffle plate to be movable in an axial direction of the baffle plate along the sidewall of the baffle plate. The driving device moves the shutter along the sidewall of the baffle plate. The plurality of through holes are disposed in the sidewall of the baffle plate so that synthesized conductance of the through holes, which are not covered by the shutter, is increased with respect to a movement amount of the shutter as the shutter is moved downward.

### TECHNICAL FIELD

Various aspects and exemplary embodiments of the present disclosure relate to a plasma processing apparatus.

### BACKGROUND

In the manufacturing of semiconductor devices or electronic devices such as flat panel displays (FPDs), a plasma processing is performed on workpieces in order to process the workpieces. For example, a plasma processing apparatus used for the plasma processing has a processing container, a placement table, a gas supply unit, and a gas discharge device. The placement table is provided in the processing container, and the gas supply unit and the gas discharge device are connected to a space within the processing container.

Recently, two or more plasma processing processes, which are performed under different pressure conditions, are required to be continuously performed in a single plasma processing apparatus. In the plasma processing processes in which pressure varies, it is advantageous to shorten a period of time for which pressure varies, that is, a transition time. In order to shorten the pressure transition time, it is advantageous to decrease the volume of a space in which a workpiece is disposed.

As a plasma processing apparatus that meets these requirements, there has been proposed, for example, a plasma processing apparatus disclosed in Patent Document 1. The plasma processing apparatus disclosed in Patent Document 1 has two baffle plates interposed between a placement table and a processing container. A first space disposed above the two baffle plates includes a region in which a workpiece is disposed, and a gas supply unit is connected to the first space. In addition, a gas discharge device is connected to a second space disposed below the two baffle members.

The two baffle plates are circular plates that extend horizontally, a plurality of openings are formed in the two baffle plates, and the openings are arranged circumferentially. In the plasma processing apparatus disclosed in Patent Document 1, a degree to which the openings of the two baffle plates vertically overlap one another is adjusted by rotating one of the two baffle plates circumferentially. Therefore, in the plasma processing apparatus disclosed in Patent Document 1, conductance between the first space and the second space is adjusted such that the pressure in the first space is adjusted.

### PRIOR ART DOCUMENT

### Patent Document

Patent Document 1: Japanese Patent Application Laid-Open No. 2001-196313

### DISCLOSURE OF THE INVENTION

### Problems to be Solved

By the way, in the plasma processing apparatus disclosed in Patent Document 1, it is difficult to set the pressure in the first space to high pressure unless an interval between the two baffle plates is set to be extremely small. That is, it is difficult to decrease the conductance between the first space and the second space unless the interval between the two baffle plates is set to be extremely small. However, when the interval between the two baffle plates is decreased, the baffle plates come into contact with each other and particles are produced in some instances.

It is necessary to increase thicknesses of the two baffle plates in order to allow the contact between the two baffle plates or precisely configure the two baffle plates such that a gap between the two baffle plates becomes small. However, in a case in which the thicknesses of the two baffle plates are large, the conductance between the first space and the second space is not greatly increased even though the two baffle plates are disposed so that the openings of the two baffle plates overlap one another. For this reason, it is difficult to decrease the pressure in the first space. Therefore, in the plasma processing apparatus disclosed in Patent Document 1, it is difficult to improve controllability of pressure in the processing space in which a workpiece is disposed. Further, a method of increasing sizes of the openings of the two baffle plates is considered to decrease the pressure in the first space, but plasma penetrates into the second space in the case in which the sizes of the openings are increased.

Weights of the baffle plates are increased when the thicknesses of the two baffle plates are increased. Therefore, a size of a driving device for driving the baffle plates is increased. Therefore, it is not practical to increase the thickness of the baffle plate or increase the size of the opening formed in the baffle plate.

### Means to Solve the Problems

One aspect of the present disclosure provides a plasma processing apparatus that performs plasma processing on a workpiece. The plasma processing apparatus includes a processing container, a placement table, a baffle plate, a shutter, and a driving device. The placement table is provided in the processing container, and the workpiece is placed on the placement table. The baffle plate has a cylindrical shape, and a plurality of through holes are formed in a sidewall thereof. The baffle plate defines a processing space above the placement table and a gas discharge space around the placement table. The shutter has a cylindrical shape, and has an inner circumferential surface having a diameter larger than a diameter of an outer circumferential surface of the baffle plate. The shutter is provided around the baffle plate to be movable in an axial direction of the baffle plate along the sidewall of the baffle plate. The driving device changes synthesized conductance made by the multiple through holes, which are not covered by the shutter, by moving the shutter along the sidewall of the baffle plate. In addition, the plurality of through holes are disposed in the side surface of the baffle plate such that a change amount in synthesized conductance of the through holes, which are not covered by the shutter, is increased with respect to a movement amount of the shutter as the shutter is moved downward.

### Effect of the Invention

According to various aspects and exemplary embodiments of the present disclosure, there is provided a plasma processing apparatus capable of improving controllability of pressure in a processing space in which a workpiece is disposed.

### BRIEF DESCRIPTION OF THE DRAWINGS

FIG. 1 is a view schematically illustrating an example of a plasma processing apparatus.

FIG. 2 is a perspective view schematically illustrating examples of a first cylindrical portion of a baffle plate and a second cylindrical portion of a shutter.

FIG. 3 is a perspective view schematically illustrating the examples of the first cylindrical portion of the baffle plate and the second cylindrical portion of the shutter.

FIG. 4 is a partially broken perspective view illustrating the examples of the baffle plate and the shutter.

FIG. 5 is a schematic view illustrating an example of an arrangement of through holes formed in a first cylindrical portion of a baffle plate according to Example 1.

FIG. 6 is a block diagram illustrating an example of a control system related to control of the shutter.

FIG. 7 is a view illustrating a first cylindrical portion of a baffle plate according to a Comparative Example.

FIG. 8 is a view illustrating an experimental result of pressure control according to the Comparative Example.

FIG. 9 is a view illustrating an example of a targeted change in pressure.

FIG. 10 is a view illustrating an example of a targeted change in conductance.

FIG. 11 is a view illustrating an example of synthesized conductance of the through holes in a region corresponding to each stroke.

FIG. 12 is a view illustrating an example of an arrangement of through holes according to Example 1.

FIG. 13 is a view illustrating an example of a simulation result of pressure control according to Example 1.

FIG. 14 is a view illustrating another example of the arrangement of the through holes formed in the first cylindrical portion of the baffle plate.

FIG. 15 is a view illustrating an example of an arrangement of through holes formed in a first cylindrical portion of a baffle plate according to Example 2.

FIG. 16 is a view illustrating an example of an evaluation result of pressure control according to Example 2.

FIG. 17 is a view illustrating examples of the number and the radii of through holes disposed in a region corresponding to each stroke.

FIG. 18 is a view illustrating another example of pressure control.

FIG. 19 is a view illustrating another example of the arrangement of the through holes formed in the first cylindrical portion of the baffle plate.

FIG. 20 is a view illustrating another example of pressure control.

FIG. 21 is a view illustrating an example of pressure pulse control.

### DETAILED DESCRIPTION TO EXECUTE THE INVENTION

Hereinafter, exemplary embodiments of a disclosed plasma processing apparatus will be described in detail with reference to the drawings. Further, the disclosed disclosure is not limited to the present exemplary embodiments.

### EXAMPLE 1

### Configuration of Plasma Processing Apparatus 10

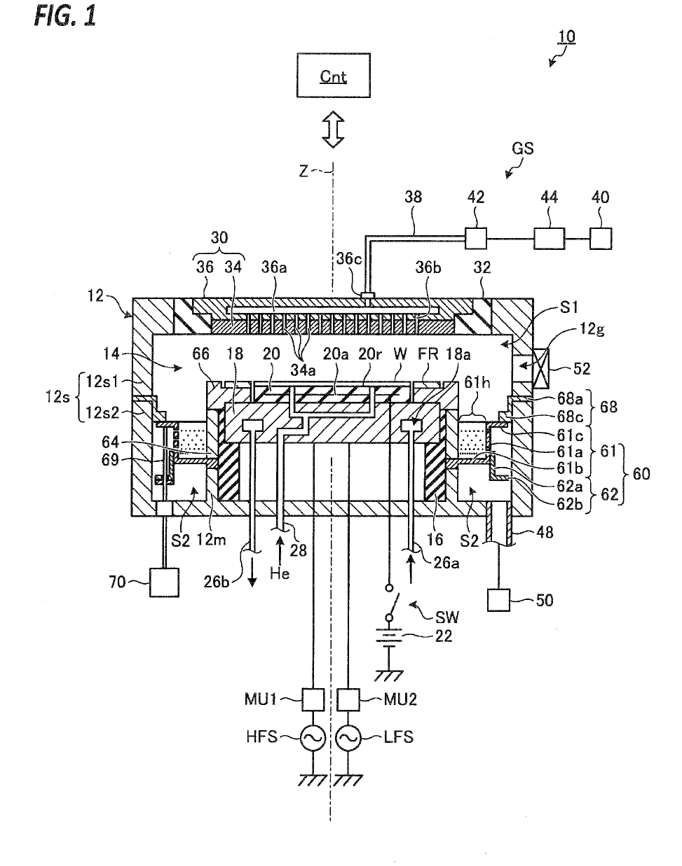

FIG. 1 is a view schematically illustrating an example of a plasma processing apparatus 10. FIG. 1 schematically illustrates a longitudinal sectional structure of the plasma processing apparatus 10. The plasma processing apparatus 10 illustrated in FIG. 1 is a capacitively-coupled parallel flat plate plasma etching apparatus. The plasma processing apparatus 10 has a processing container 12. The processing container 12 is configured by, for example, aluminum having an anodized surface. The processing container 12 has a sidewall 12s. The sidewall 12s has an approximately cylindrical shape. An axis Z indicates a central axis of the sidewall 12s. An opening 12g for loading or unloading a wafer W, which is an example of a workpiece, is formed in the sidewall 12s. The opening 12g is configured to be openable or closable by a gate valve 52.

A placement table 14 is provided in the processing container 12. The placement table 14 is supported by a support unit 16. The support unit 16 is an insulating member having an approximately cylindrical shape and extends upward from a bottom portion of the processing container 12. In the present Example, the support unit 16 is in contact with a lower circumferential edge portion of the placement table 14 and supports the placement table 14.

The placement table 14 includes a lower electrode 18 and an electrostatic chuck 20. The lower electrode 18 has an approximately disk shape and is made of a conductor. A first high-frequency power source HFS is connected to the lower electrode 18 via a matching device MU1. The first high-frequency power source HFS is a power source that mainly generates high-frequency electric power for producing plasma, and for example, the first high-frequency power source HFS generates high-frequency electric power of 27 MHz to 100 MHz. In the present Example, the first high-frequency power source HFS generates, for example, high-frequency electric power of 40 MHz. The matching device MU1 matches output impedance of the first high-frequency power source HFS with input impedance at a load side (lower electrode 18 side).

A second high-frequency power source LFS is connected to the lower electrode 18 via a matching device MU2. The second high-frequency power source LFS mainly generates high-frequency electric power (high-frequency bias electric power) for implanting ions into the wafer W, and supplies the high-frequency bias electric power to the lower electrode 18. A frequency of the high-frequency bias electric power is, for example, a frequency within a range of 400 kHz to 13.56 MHz. In the present Example, the second high-frequency power source LFS supplies high-frequency bias electric power of, for example, 3 MHz to the lower electrode 18. The matching device MU2 matches output impedance of the second high-frequency power source LFS with input impedance at the load side (lower electrode 18 side).

The electrostatic chuck 20 is provided on the lower electrode 18. The electrostatic chuck 20 has a structure in which an electrode 20a, which is a conductive film, is disposed between a pair of insulating layers or insulating sheets. A direct current power source 22 is electrically connected to the electrode 20a via a switch SW. An upper surface of the electrostatic chuck 20 defines a placement region 20r in which the wafer W is placed. When direct current voltage is applied from the direct current power source 22 to the electrode 20a of the electrostatic chuck 20, the electrostatic chuck 20 draws and holds the wafer W placed in the placement region 20r with electrostatic force such as Coulomb's force.

The plasma processing apparatus 10 is provided with a focus ring FR that surrounds an edge of the wafer W. The focus ring FR is made of, for example, silicon or quartz.

A flow path 18a is formed in the lower electrode 18. A refrigerant such as a coolant is supplied to the flow path 18a through a pipe 26a from a chiller unit provided outside the plasma processing apparatus 10. The refrigerant supplied to the flow path 18a returns back to the chiller unit through a pipe 26b. A temperature of the refrigerant, which circulates in the flow path 18a, is controlled by the chiller unit such that a temperature of the wafer W placed on the electrostatic chuck 20 is controlled.

A pipe 28 is provided in the placement table 14. The pipe 28 supplies heat transfer gas, such as He gas, which is supplied from a heat transfer gas supply mechanism, to a portion between the upper surface of the electrostatic chuck 20 and a rear surface of the wafer W.

The plasma processing apparatus 10 has an upper electrode 30. The upper electrode 30 is disposed above the lower electrode 18 so as to face the lower electrode 18. The lower electrode 18 and the upper electrode 30 are provided in the processing container 12 so as to be approximately in parallel with each other.

The upper electrode 30 is supported on a ceiling portion of the processing container 12 through an insulating shielding member 32. The upper electrode 30 includes an electrode plate 34 and an electrode support body 36. The electrode plate 34 faces a space in the processing container 12 and has a plurality of gas discharge holes 34a. The electrode plate 34 is made of a conductor or a semiconductor with low Joule heat and low resistance.

The electrode support body 36 is made of a conductive material such as aluminum and supports the electrode plate 34 so that the electrode plate 34 is detachable. The electrode support body 36 has a water-cooled structure. A gas diffusion chamber 36a is provided in the electrode support body 36. A plurality of gas flow holes 36b, which communicate with the gas discharge holes 34a, extend downward from the gas diffusion chamber 36a. In addition, a gas introducing port 36c, which introduces processing gas into the gas diffusion chamber 36a, is formed in the electrode support body 36. A gas supply pipe 38 is connected to the gas introducing port 36c.

A gas source group 40 is connected to the gas supply pipe 38 via a valve group 42 and a flow rate controller group 44. The gas source group 40 has a plurality of gas sources. The plurality of gas sources are sources having a plurality of different types of gases. The valve group 42 has a plurality of valves. The flow rate controller group 44 has a plurality of flow rate controllers. Each of the flow rate controllers is, for example, a mass flow controller or the like. Each of the gas sources of the gas source group 40 is connected to the gas supply pipe 38 via one valve of the valve group 42 and one flow rate controller of the flow rate controller group 44.

In the plasma processing apparatus 10, gas from one or more gas sources selected from the plurality of gas sources of the gas source group 40 is supplied to the gas supply pipe 38 in a state in which a flow rate of the gas is controlled by the corresponding flow rate controller and the corresponding valve. The gas supplied into the gas supply pipe 38 is diffused into the gas diffusion chamber 36a and supplied into the space in the processing container 12 through the gas flow holes 36b and the gas discharge hole 34a. Further, in the present Example, the gas source group 40, the flow rate controller group 44, the valve group 42, the gas supply pipe 38, and the upper electrode 30 constitute a gas supply unit GS. The gas supply unit GS is connected to a first space S1 to be described below.

As illustrated in FIG. 1, a gas discharge pipe 48 is connected to the bottom portion of the processing container 12, and a gas discharge device 50 is connected to the gas discharge pipe 48. The gas discharge device 50 is connected to a second space S2 to be described below via the gas discharge pipe 48. The gas discharge device 50 has a vacuum pump such as a turbo molecular pump.

The plasma processing apparatus 10 has a control unit Cnt. For example, the control unit Cnt is a computer having a processor, a storage unit, an input device, a display device, and the like, and controls respective parts of the plasma processing apparatus 10. The control unit Cnt receives, through the input device, an operator's operation of inputting a command for managing the plasma processing apparatus 10. In addition, the control unit Cnt visualizes and displays, on the display device, an operational situation of the plasma processing apparatus 10, and the like. In addition, the storage unit of the control unit Cnt stores a control program for controlling various types of processes to be performed in the plasma processing apparatus 10 by the processor or a program, that is, a processing recipe or the like for performing processing on respective configurations of the plasma processing apparatus 10 in accordance with processing conditions.

In the plasma processing apparatus 10 configured as described above, gas is supplied into the processing container 12 from one or more gas sources selected from the plurality of gas sources of the gas source group 40 in order to process the wafer W. Further, as high-frequency electric power for producing plasma is applied to the lower electrode 18, a high-frequency electric field is generated between the lower electrode 18 and the upper electrode 30. With the high-frequency electric field, plasma of the gas supplied into the processing container 12 is produced. Further, the wafer W, which is drawn and held on the electrostatic chuck 20, is processed, for example, etched by the produced plasma. Further, ions may be implanted into the wafer W by applying the high-frequency bias electric power to the lower electrode 18.

[Baffle Structure 60]

For example, as illustrated in FIG. 1, the plasma processing apparatus 10 further includes a baffle structure 60. The baffle structure 60 is disposed between the placement table 14 and the sidewall 12s of the processing container 12 below the placement region 20r. The baffle structure 60 defines the first space S1 and the second space S2 in the processing container 12. The first space S1 is a space including a space above the placement table 14. The second space S2 is a space around the placement table 14. The aforementioned gas supply unit GS is connected to the first space S1, and the aforementioned gas discharge device 50 is connected to the second space S2. The first space S1 is an example of a processing space, and the second space S2 is an example of a gas discharge space.

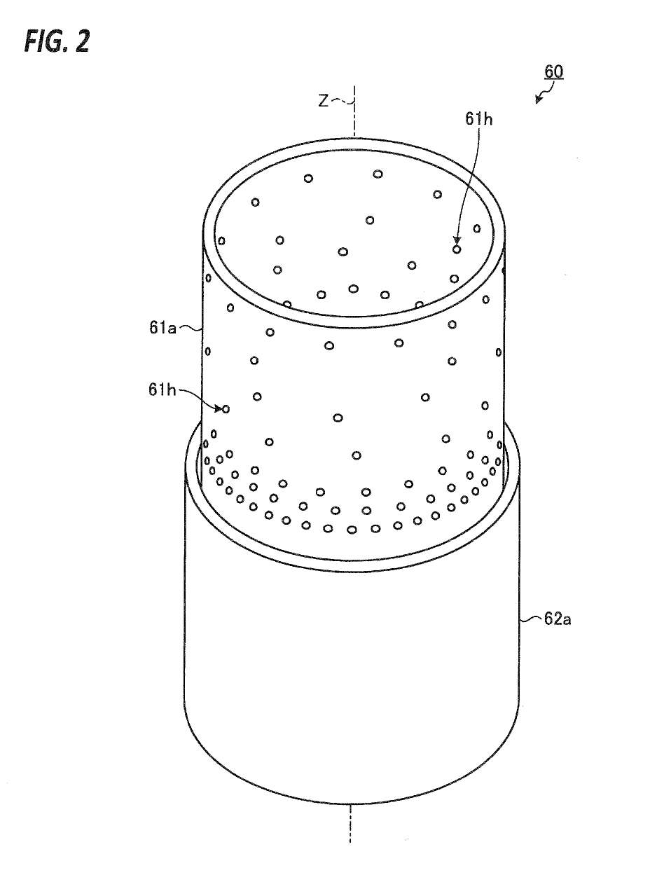

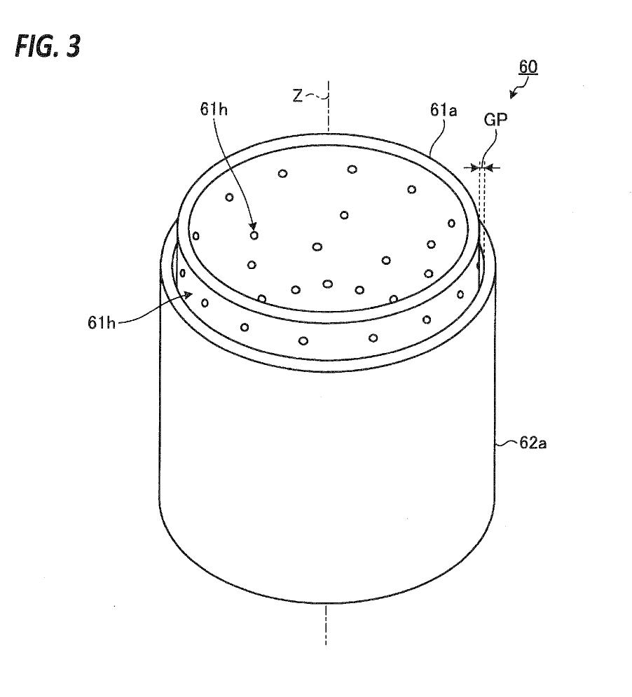

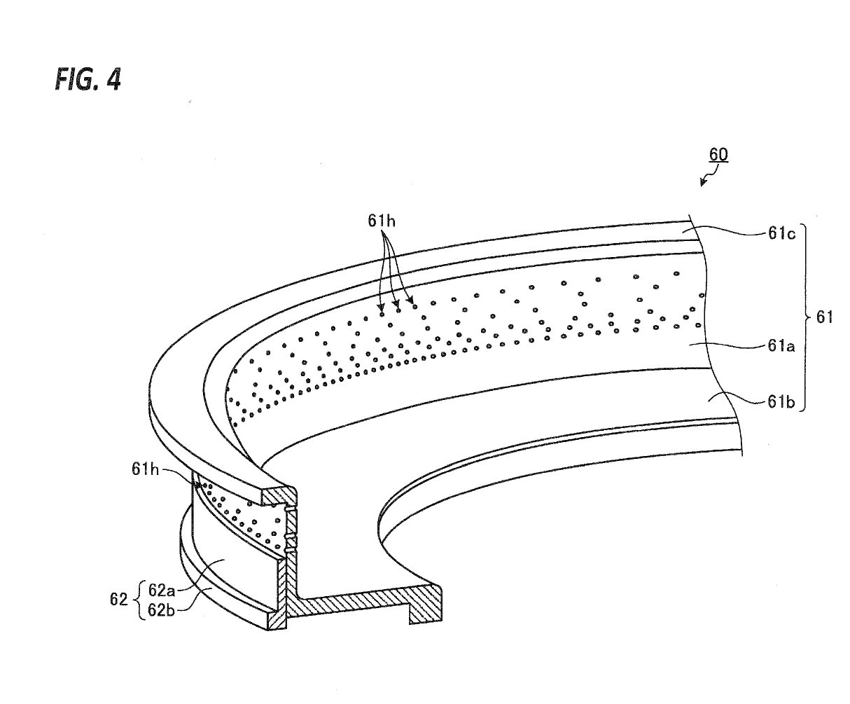

Next, the description will be made with reference to FIGS. 2 to 4 together with FIG. 1. FIGS. 2 and 3 are perspective views schematically illustrating examples of a first cylindrical portion 61a of a baffle plate 61 and a second cylindrical portion 62a of a shutter 62. FIG. 4 is a breakaway perspective view illustrating the examples of the baffle plate 61 and the shutter 62. Further, FIGS. 2 to 4 are views illustrated for the sake of understanding of the description. For this reason, an aspect ratio between the first cylindrical portion 61a and the second cylindrical portion 62a and the size and the number of through holes 61h formed in the first cylindrical portion 61a, which are illustrated in FIGS. 2 to 4, are different from the actual aspect ratio between the first cylindrical portion 61a and the second cylindrical portion 62a and the actual size and the actual number of through holes 61h formed in the first cylindrical portion 61a. For example, as illustrated in FIGS. 1 and 4, the baffle structure 60 includes the baffle plate 61 and the shutter 62.

[Structure of Baffle Plate 61]

For example, the baffle plate 61 is made by coating a surface of metal such as aluminum or stainless steel with a coating such as Y₂O₃. The baffle plate 61 has the first cylindrical portion 61a, a lower annular portion 61b, and an upper annular portion 61c. The first cylindrical portion 61a is an example of a sidewall of the baffle plate 61.

For example, as illustrated in FIG. 1 and FIGS. 2 to 4, the first cylindrical portion 61a has an approximately cylindrical shape and is provided in the processing container 12 so that a central axis of the first cylindrical portion 61a approximately coincides with the axis Z. In the present Example, a plate thickness of the first cylindrical portion 61a is, for example, 5 mm. In addition, in the present Example, a diameter of an outer circumferential surface of the first cylindrical portion 61a is, for example, 550 mm. For example, as illustrated in FIG. 1, the first cylindrical portion 61a is provided between the placement table 14 and the sidewall 12s of the processing container 12.

For example, as illustrated in FIG. 1 and FIGS. 2 to 4, the plurality of through holes 61h are formed in the first cylindrical portion 61a. Each of the through holes 61h penetrates the first cylindrical portion 61a radially (i.e., in a radial direction) with respect to the axis Z. In the present Example, an opening of each of the through holes 61h has an approximately circular shape, and a radius of the through hole 61h is, for example, 1 mm. In the present Example, shapes and areas of the openings of the through holes 61h are equal to one another. Further, as another example, the opening of each of the through holes 61h may have an elliptical shape, a long circular shape, a polygonal shape, or the like.

For example, as illustrated in FIGS. 1 and 4, the lower annular portion 61b has an annular shape. The lower annular portion 61b is continuously connected to a lower end of the first cylindrical portion 61a and extends radially inward from the lower end of the first cylindrical portion 61a. In addition, the upper annular portion 61c has an annular shape. The upper annular portion 61c is continuously connected to an upper end of the first cylindrical portion 61a and extends radially outward from the upper end of the first cylindrical portion 61a. In the present Example, the first cylindrical portion 61a, the lower annular portion 61b, and the upper annular portion 61c of the baffle plate 61 are integrally formed, for example. Further, as another example, the first cylindrical portion 61a, the lower annular portion 61b, and the upper annular portion 61c may be made as separate members, and the baffle plate 61 may be made by assembling the first cylindrical portion 61a, the lower annular portion 61b, and the upper annular portion 61c.

For example, as illustrated in FIG. 1, the bottom portion of the processing container 12 includes an approximately cylindrical support portion 12m. A cylindrical member 64 is provided above the support portion 12m. The cylindrical member 64 is made of, for example, an insulator such as ceramic. The cylindrical member 64 extends along an outer circumferential surface of the support unit 16. In addition, an annular member 66 is provided on the cylindrical member 64 and the support unit 16. The annular member 66 is made of, for example, an insulator such as ceramic. The annular member 66 extends to the vicinity of an edge of the electrostatic chuck 20 along an upper surface of the lower electrode 18. The aforementioned focus ring FR is provided on the annular member 66.

An inner edge portion of the lower annular portion 61b of the baffle plate 61 is disposed between the support portion 12m and the cylindrical member 64. The support portion 12m and the cylindrical member 64 are coupled to each other by, for example, a screw. Therefore, the inner edge portion of the lower annular portion 61b of the baffle plate 61 is interposed and supported between the support portion 12m and the cylindrical member 64.

For example, as illustrated in FIG. 1, the sidewall 12s of the processing container 12 includes an upper portion 12s1 and a lower portion 12s2. In addition, the plasma processing apparatus 10 has a support member 68. The support member 68 has an upper portion 68a having an approximately annular shape, and a lower portion 68c having an approximately annular shape. The upper portion 68a and the lower portion 68c are connected to each other via an intermediate portion having an approximately cylindrical shape. The upper portion 68a of the support member 68 is interposed and supported between the upper portion 12s1 and the lower portion 12s2 of the sidewall 12s. In addition, the lower portion 68c of the support member 68 extends radially inward in the processing container 12. The upper annular portion 61c of the baffle plate 61 is fixed to the lower portion 68c of the support member 68 by, for example, a screw. In the present Example, the upper portion 68a, the intermediate portion, and the lower portion 68c of the support member 68 are integrally formed, for example. Further, as another example, the upper portion 68a, the intermediate portion, and the lower portion 68c may be made as separate members, and the support member 68 may be made by assembling the upper portion 68a, the intermediate portion, and the lower portion 68c.

[Structure of Shutter 62]

For example, the shutter 62 may be made by coating a surface of metal such as aluminum or stainless steel with a coating such as Y₂O₃. For example, as illustrated in FIGS. 1 and 4, the shutter 62 has the second cylindrical portion 62a and an annular portion 62b. For example, as illustrated in FIG. 1 and FIGS. 2 to 4, the second cylindrical portion 62a has an approximately cylindrical shape and is provided in the processing container 12 so that a central axis of the second cylindrical portion 62a approximately coincides with the axis Z. In addition, a diameter of an inner circumferential surface of the second cylindrical portion 62a is larger than a diameter of an outer circumferential surface of the first cylindrical portion 61a of the baffle plate 61. In the present Example, the diameter of the inner circumferential surface of the second cylindrical portion 62a is, for example, 550.1 mm, and a plate thickness of the second cylindrical portion 62a is, for example, 5 mm. Further, in the present Example, the diameter of the outer circumferential surface of the first cylindrical portion 61a is, for example, 550 mm, and a central axis of the first cylindrical portion 61a and a central axis of the second cylindrical portion 62a approximately coincide with the axis Z. Therefore, for example, as illustrated in FIG. 3, a gap GP of, for example, 0.1 mm is present between an outer circumference of the first cylindrical portion 61a and an inner circumference of the second cylindrical portion 62a. Therefore, the second cylindrical portion 62a may be moved in a direction of the axis Z along the first cylindrical portion 61a without coming into contact with the first cylindrical portion 61a. For this reason, it is possible to inhibit particles from being produced when the shutter 62 is moved along the first cylindrical portion 61a of the baffle plate 61.

For example, as illustrated in FIGS. 1 and 4, the annular portion 62b of the shutter 62 has an approximately annular shape. In the present Example, the annular portion 62b is continuously connected to a lower end of the second cylindrical portion 62a and extends radially outward. In the present Example, the second cylindrical portion 62a and the annular portion 62b of the shutter 62 are integrally formed, for example. Further, as another example, the second cylindrical portion 62a and the annular portion 62b may be made as separate members, and the shutter 62 may be made by assembling the second cylindrical portion 62a and the annular portion 62b.

For example, as illustrated in FIG. 1, the annular portion 62b of the shutter 62 is connected to a shaft body 69. In the present Example, the shaft body 69 is, for example, a feed screw, and the annular portion 62b is connected to the shaft body 69 by a nut. In addition, the shaft body 69 is connected to a driving device 70. The driving device 70 is, for example, a motor. The driving device 70 moves the shutter 62 upward and downward along the shaft body 69. Therefore, the second cylindrical portion 62a of the shutter 62 is moved upward and downward between the first cylindrical portion 61a of the baffle plate 61 and the sidewall 12s of the processing container 12. Further, while FIG. 1 illustrates the single shaft body 69, but the plurality of shaft bodies 69, which are arranged circumferentially, may be connected to the annular portion 62b of the shutter 62.

For example, as illustrated in FIGS. 2 and 3, the second cylindrical portion 62a of the shutter 62 may be moved upward and downward by the driving device 70 in the direction of the axis Z along the outer circumferential surface of the first cylindrical portion 61a. When the second cylindrical portion 62a is moved downward, the number of through holes 61h, which are covered by the second cylindrical portion 62a, is decreased. Therefore, synthesized conductance of the baffle structure 60, which is made by the plurality of through holes 61h that are not covered by the second cylindrical portion 62a, is increased.

For example, as illustrated in FIG. 2, when the shutter 62 is positioned at a lowermost side within a movement range of the shutter 62, none of the through holes 61h formed in the first cylindrical portion 61a are covered by the second cylindrical portion 62a. That is, all of the through holes 61h formed in the first cylindrical portion 61a communicate directly with the second space S2. Therefore, the synthesized conductance of the baffle structure 60, which is made by the plurality of through holes 61h that are not covered by the second cylindrical portion 62a, is maximized. Therefore, the pressure in the first space S1 becomes close to the pressure in the second space S2 such that the pressure in the first space S1 may be set to low pressure.

When the second cylindrical portion 62a is moved upward, the number of through holes 61h, which are covered by the second cylindrical portion 62a, is increased. Therefore, the synthesized conductance of the baffle structure 60, which is made by the plurality of through holes 61h that are not covered by the second cylindrical portion 62a, is decreased. Further, for example, as illustrated in FIG. 3, when the shutter 62 is positioned at an uppermost side within the movement range of the shutter 62, the through holes 61h, except for the through holes 61h formed at an uppermost stage of the first cylindrical portion 61a, are covered by the second cylindrical portion 62a. Therefore, the synthesized conductance of the baffle structure 60, which is made by the plurality of through holes 61h that are not covered by the second cylindrical portion 62a, is minimized. Therefore, the pressure in the first space S1 becomes higher than the pressure in the second space S2 such that the pressure in the first space S1 may be set to high pressure.

Here, the baffle plate 61 and the shutter 62 have an approximately cylindrical shape such that in comparison with a case in which the baffle plate 61 and the shutter 62 have a disk shape, the structure of the baffle plate 61 and the structure of the shutter 62 are hardly deformed by an influence of the pressure in the first space S1. For this reason, it is possible to ensure mechanical strength even without greatly increasing thicknesses of the baffle plate 61 and the shutter 62. Therefore, the synthesized conductance of the baffle structure 60 may be sufficiently low when the shutter 62 is moved to the uppermost position, and the synthesized conductance of the baffle structure 60 may be sufficiently high when the shutter 62 is moved to the lowermost position. Therefore, the plasma processing apparatus 10 of the present Example may improve controllability of pressure in the first space S1.

For example, as illustrated in FIG. 3, the gap GP is present between the first cylindrical portion 61a and the second cylindrical portion 62a. For this reason, in the case in which the shutter 62 is positioned at the uppermost side within the movement range of the shutter 62, the synthesized conductance of the baffle structure 60 is the synthesized conductance of conductance of the respective through holes 61h formed at the uppermost stage of the first cylindrical portion 61a and conductance of a flow path formed by the gap GP and the through holes 61h except for the aforementioned through holes 61h. Therefore, in the case in which the shutter 62 is positioned at the uppermost side within the movement range of the shutter 62, the synthesized conductance of the baffle structure 60 has a higher value than the synthesized conductance of the respective through holes 61h formed at the uppermost stage of the first cylindrical portion 61a.

[Arrangement of Through Holes 61h]

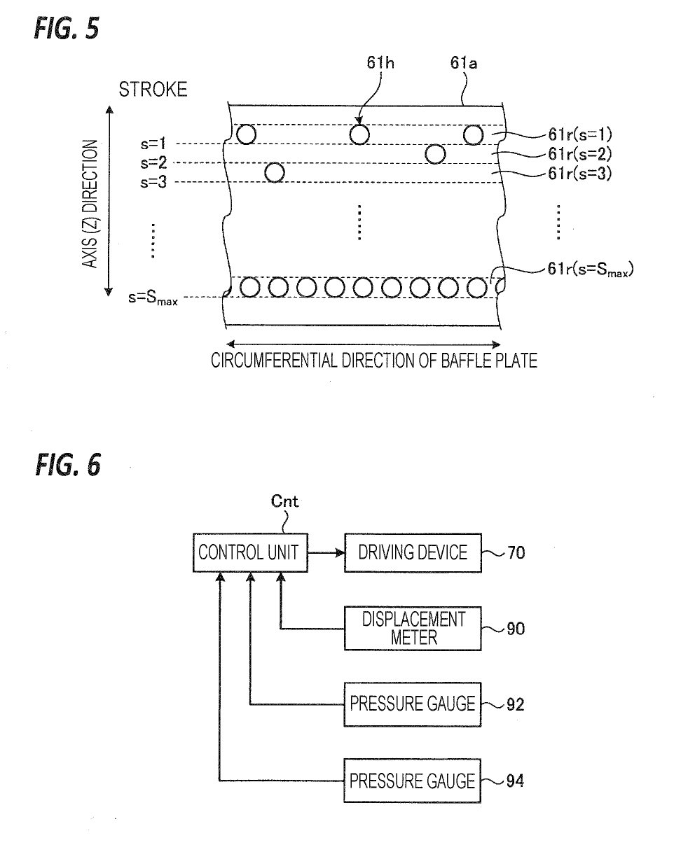

Here, an arrangement of the plurality of through holes 61h formed in the first cylindrical portion 61a will be described with reference to FIG. 5. FIG. 5 is a schematic view illustrating an example of an arrangement of the through holes 61h formed in the first cylindrical portion 61a of the baffle plate 61 according to Example 1. For example, as illustrated in FIG. 5, in the first cylindrical portion 61a, one or more through holes 61h are disposed in each region 61r for each predetermined length in the direction of the axis Z. For example, as illustrated in FIG. 5, in the first cylindrical portion 61a, each of the regions 61r extends in a direction intersecting the direction of the axis Z, for example, each of the regions 61r extends in a direction orthogonal to the direction of the axis Z. In the present Example, for example, as illustrated in FIG. 5, a width of each of the regions 61r in the direction of the axis Z is approximately equal to a diameter of the through hole 61h disposed in the region 61r. Therefore, it is possible to decrease the movement range of the shutter 62 when controlling the pressure in the first space S1 by moving the shutter 62.

The plurality of regions 61r are disposed in the direction of the axis Z, and one or more through holes 61h are disposed in each of the regions 61r. For this reason, the number of through holes 61h, which are not covered by the second cylindrical portion 62a of the shutter 62, is increased as the shutter 62 is moved downward. For this reason, the synthesized conductance of the through holes 61h, which are not covered by the second cylindrical portion 62a, is increased as the shutter 62 is moved downward. In the present Example, values of conductance of the respective through holes 61h are approximately equal to one another since the shapes and the areas of the openings of the respective through holes 61h are approximately equal to one another. For this reason, if the numbers of through holes 61h included in the respective regions 61r are equal to one another, the change amount in synthesized conductance of the through holes 61h, which are not covered by the second cylindrical portion 62a, is constant with respect to the movement amount of the shutter 62.

In contrast, in the present Example, the through holes 61h are disposed in the first cylindrical portion 61a of the baffle plate 61 so that the change amount in synthesized conductance of the through holes 61h, which are not covered by the second cylindrical portion 62a, is increased with respect to the movement amount of the shutter 62 as the shutter 62 is moved downward. For example, in a range of the position of the shutter 62 at which the number of through holes 61h, which are covered by the second cylindrical portion 62a, is larger than a first number, the change amount in synthesized conductance of the through holes 61h, which are not covered by the second cylindrical portion 62a, with respect to the movement amount of the shutter 62 is defined as ΔC₁. In addition, in a range of the position of the shutter 62 at which the number of through holes 61h, which are covered by the second cylindrical portion 62a, is smaller than the first number, the change amount in synthesized conductance of the through holes 61h, which are not covered by the second cylindrical portion 62a, with respect to the movement amount of the shutter 62 is defined as ΔC₂. In the case in which ΔC₁ and ΔC₂ are defined as described above, the through holes 61h are disposed in the first cylindrical portion 61a of the baffle plate 61 so that ΔC₁<ΔC₂ is satisfied.

In the present Example, since the values of conductance of the respective through holes 61h are approximately equal to one another, the through holes 61h are disposed in the first cylindrical portion 61a of the baffle plate 61 so that for example, as illustrated in FIG. 5, in the region 61r below the second region 61r from the top side, the number of through holes 61h included in the region 61r is increased as the position of the region 61r is lowered.

In the present Example, the number of through holes 61h included in the region 61r at the uppermost stage is set to the number by which conductance for achieving predetermined pressure as an initial value is implemented. Therefore, in the present Example, the number of through holes 61h included in the region 61r at the uppermost stage becomes larger than the number of through holes 61h included in the second region 61r from the top side.

In each of the regions 61r on the first cylindrical portion 61a, the through holes 61h disposed in the region 61r are disposed in the region 61r so that intervals between the adjacent through holes 61h in the region 61r are approximately uniform. In addition, the respective through holes 61h are disposed in the first cylindrical portion 61a so that the respective through holes 61h less overlap the other through holes 61h in the direction of the axis Z. Therefore, it is possible to inhibit a flow of gas passing through the plurality of through holes 61h from circumferentially deviating.

The respective regions 61r are regions on the first cylindrical portion 61a through which the upper end of the second cylindrical portion 62a passes when a stroke caused by the movement of the shutter 62 is changed by one step. In the present Example, the stroke is a position of the shutter 62 in the direction of the axis Z.

The shutter 62 is moved by a predetermined distance in the direction of the axis Z, and numbers s, which are integers, are assigned to the respective strokes of the shutter 62 in the ascending order from 1 from the top side to the bottom side. For example, when the shutter 62 is positioned at the uppermost side as illustrated in FIG. 3, the number of the stroke of the shutter 62 at this position is 1. Further, when the shutter 62 is moved downward by a predetermined distance, the number of the stroke of the shutter 62 at the position after the shutter 62 is moved is 2. Hereinafter, the stroke, to which a number having a value of s is assigned, is referred to as a stroke s.

Numbers, which are integers, are assigned to the respective regions 61r in the ascending order from 1 from the top side to the bottom side. The numbers, which are assigned to the respective regions 61r, correspond to the numbers of the strokes of the shutter 62. For example, when the shutter 62 is moved from a stroke s-1 to the stroke s, the upper end of the second cylindrical portion 62a passes through the region 61r to which the number s is assigned.

For example, when the value of the stroke of the shutter 62 is 1, the upper end of the second cylindrical portion 62a is positioned between the region 61r positioned at the uppermost side and the region 61r adjacent to and below the region 61r positioned at the uppermost side. Since the number assigned to the region 61r positioned at the uppermost side is 1, only the region 61r to which the number 1 is assigned is not covered by the second cylindrical portion 62a of the shutter 62 when the value of the stroke of the shutter 62 is 1. In addition, when the value of the stroke of the shutter 62 is n, the upper end of the second cylindrical portion 62a is positioned between the region 61r to which the number n is assigned and the region 61r to which the number n+1 is assigned and which is adjacent to and below the region 61r to which the number n is assigned. For this reason, when the value of the stroke of the shutter 62 is n, a portion from the region 61r to which the number 1 is assigned to the region 61r to which the number n is assigned is not covered by the second cylindrical portion 62a of the shutter 62. In addition, when the value of the stroke of the shutter 62 is a maximum value sₘₐₓ, the upper end of the second cylindrical portion 62a is positioned at a lower end of the region 61r to which the number sₘₐₓ is assigned. For this reason, when the value of the stroke of the shutter 62 is sₘₐₓ, none of the regions 61r are covered by the second cylindrical portion 62a of the shutter 62. Further, hereinafter, the region 61r to which the number s, which is equal to the number s of the stroke, is assigned, is referred to as the region 61r corresponding to the stroke s.

In the present Example, the number of through holes 61h covered by the shutter 62 is large at a position of the shutter 62 at which the value of the stroke is small, and the number of through holes 61h covered by the shutter 62 is small at a position of the shutter 62 at which the value of the stroke is large.

FIG. 6 is a block diagram illustrating an example of a control system related to control of the shutter 62. For example, as illustrated in FIG. 6, the driving device 70 is controlled by the control unit Cnt. The control unit Cnt receives signals from a displacement meter 90, a pressure gauge 92, and a pressure gauge 94. The displacement detector 90 measures a distance from a position of the shutter 62 or from a reference position in the direction of the axis Z, and transmits a signal, which indicates a measurement result, to the control unit Cnt. The pressure gauge 92 measures the pressure in the first space S1, and transmits a signal, which indicates a measurement result, to the control unit Cnt. The pressure gauge 94 measures the pressure in the second space S2, and transmits a signal, which indicates a measurement result, to the control unit Cnt.

Based on the signals indicating the measurement results from the pressure gauge 92 and the pressure gauge 94, the control unit Cnt calculates a position of the shutter 62 in the direction of the axis Z at which the pressure in the first space S1 becomes pressure designated by the recipe. Further, based on the calculated position of the shutter 62 and the signal indicating the measurement result from the displacement meter 90, the control unit Cnt calculates the movement amount of the shutter 62. Further, the control unit Cnt transmits a signal, which indicates the calculated movement amount of the shutter 62, to the driving device 70. Based on the signal from the control unit Cnt, the driving device 70 moves the shutter 62 in the direction of the axis Z.

According to the plasma processing apparatus 10 configured as described above, it is possible to adjust a proportion of the plurality of through holes 61h covered by the second cylindrical portion 62a to the second space S2 by adjusting a positional relationship in the vertical direction between the first cylindrical portion 61a of the baffle plate 61 and the second cylindrical portion 62a of the shutter 62. Therefore, it is possible to adjust conductance between the first space S1 and the second space S2. Therefore, it is possible to set the pressure in the first space S1 to any pressure.

### COMPARATIVE EXAMPLE

Here, controllability of pressure in the processing container 12 in a case in which a baffle plate 61 according to a Comparative Example is used will be described. FIG. 7 is a view illustrating a first cylindrical portion 61a′ of the baffle plate 61 according to the Comparative Example. For example, as illustrated in FIG. 7, a plurality of through holes 61h′ are formed in the first cylindrical portion 61a′ of the baffle plate 61 according to the Comparative Example. Each of the through holes 61h′ has a longitudinal slit shape in the vertical direction. The through holes 61h′ are arranged circumferentially with respect to the axis Z at an approximately uniform pitch so that the through holes 61h′ are distributed around the entire first cylindrical portion 61a′.

[Change in Pressure in First Space S1 according to Comparative Example]

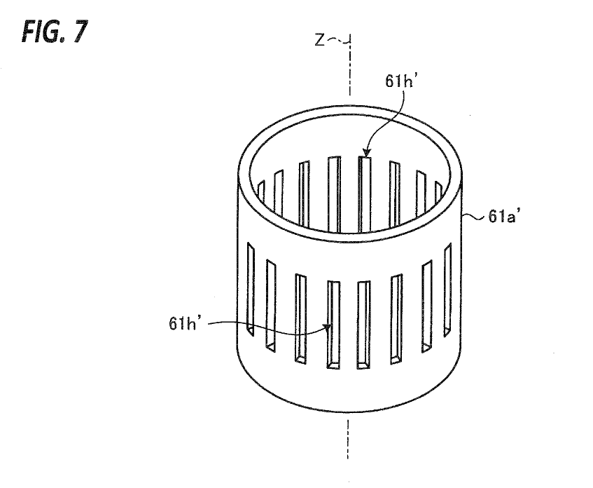

FIG. 8 is a view illustrating an experimental result of pressure control according to the Comparative Example. In FIG. 8, the vertical axis indicates the pressure in the first space S1, and the horizontal axis indicates the stroke of the shutter 62. As the shutter 62 is moved downward, a proportion of the respective through holes 61h′ formed in the first cylindrical portion 61a′, which are covered by the second cylindrical portion 62a of the shutter 62, is decreased. For this reason, synthesized conductance of the baffle structure 60 according to the Comparative Example is increased by moving the shutter 62 downward. Therefore, the pressure in the first space S1 is decreased by moving the shutter 62 downward.

However, as apparent from FIG. 8, the pressure in the first space S1 is rapidly decreased in accordance with the movement of the shutter 62 in a region in which a proportion of the respective through holes 61h′ covered by the shutter 62 is high (a region in which the value of the stroke is small). Meanwhile, in a region in which a proportion of the respective through holes 61h′ covered by the shutter 62 is low (a region in which the value of the stroke is large), the amount of decrease in pressure in the first space S1 is small even though the shutter 62 is moved. For this reason, it is difficult to set the pressure in the first space S1 to a desired pressure by controlling the stroke of the shutter 62. That is, in the plasma processing apparatus 10 according to the Comparative Example, controllability of pressure is low when controlling the pressure in the first space S1 by the shutter 62.

[Method of Determining Arrangement of Through Holes 61h]

Here, an arrangement of the through holes 61h formed in the first cylindrical portion 61a of the baffle plate 61 according to the present Example will be described. To improve controllability of pressure when controlling the pressure in the first space S1 by moving the shutter 62, the pressure in the first space S1 may be linearly changed with respect to the movement amount of the shutter 62. For example, FIG. 9 illustrates an ideal change in pressure in the first space S1 with respect to the stroke of the shutter 62. FIG. 9 is a view illustrating an example of a targeted change in pressure. In the example in FIG. 9, the pressure in the first space S1 is linearly changed with respect to the strokes of 1 to 50.

For example, in a case in which the pressure in the first space S1 is rectilinearly changed with respect to the stroke, the pressure P(s) in the first space S1 in the case in which the shutter 62 is positioned at the stroke s is expressed as follows using the stroke s as a variable.

$$\begin{matrix}[ Equation 1 ] & \\ P ( s ) = \frac{{P}_{min} - {P}_{max}}{{S}_{max} - 1} s + {P}_{min} - \frac{{P}_{min} - {P}_{max}}{{S}_{max} - 1} {S}_{max} & ( 1 )\end{matrix}$$

Here, Pₘₐₓ indicates the pressure in the first space S1 at the position of the shutter 62 at which the value of the stroke s is 1. In the present Example, the through holes 61h at the uppermost stage of the first cylindrical portion 61a are not covered by the second cylindrical portion 62a even though the shutter 62 is positioned at the uppermost side. In addition, Pₘᵢₙ indicates the pressure in the first space S1 at the position of the shutter 62 at which the value of the stroke s is a maximum value Sₘₐₓ.

P(s) indicated in Equation 1 is considered as a linear function related to the variable s, and as indicated below, an inclination is set to α, and a segment is set to β.

$$\begin{matrix}[ Equation 2 ] & \\ \begin{matrix}\frac{{P}_{min} - {P}_{max}}{{S}_{max} - 1} = α \\ {P}_{min} - \frac{{P}_{min} - {P}_{max}}{{S}_{max} - 1} {S}_{max} = β\end{matrix} \} & ( 2 )\end{matrix}$$

Therefore, a straight line indicated in the aforementioned Equation 1 is expressed as the following Equation 3.

[Equation 3]

P(s)=αs+β (3)

When an inclination of the straight line illustrated in FIG. 9 is set to −α, the following relationship is satisfied so that the straight line expressed as the aforementioned Equation 3 becomes the straight line illustrated in FIG. 9.

$$\begin{matrix}[ Equation 4 ] & \\ \frac{d}{ds} P ( s ) = - α & ( 4 )\end{matrix}$$

Here, it has been known that assuming that a mass flow rate of gas supplied into the processing container 12 is Q, synthesized conductance C of the baffle structure 60 when the pressure in the first space S1 is P(s) is generally obtained from the following Equation.

$$\begin{matrix}[ Equation 5 ] & \\ C = \frac{Q}{P ( s )} & ( 5 )\end{matrix}$$

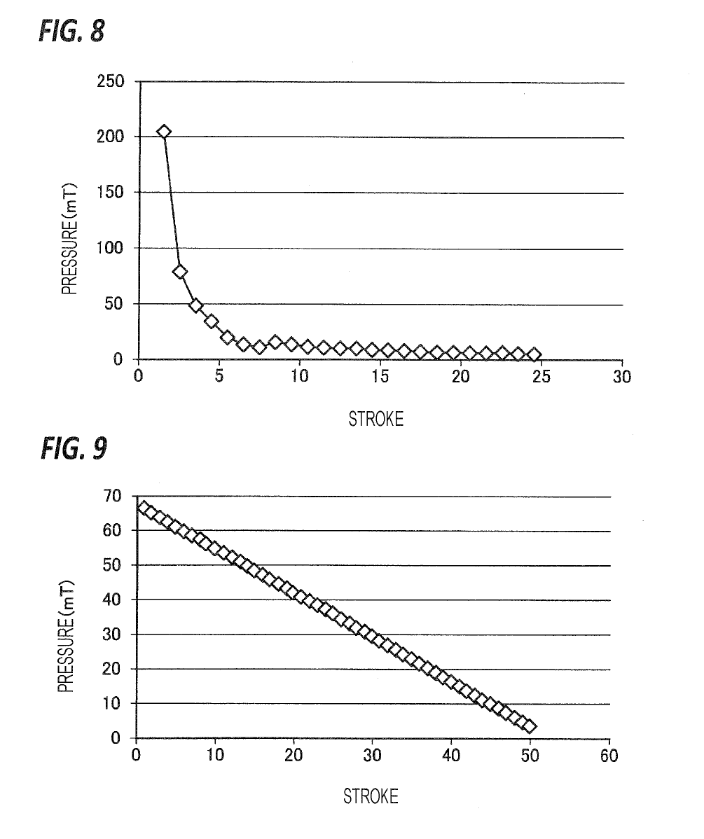

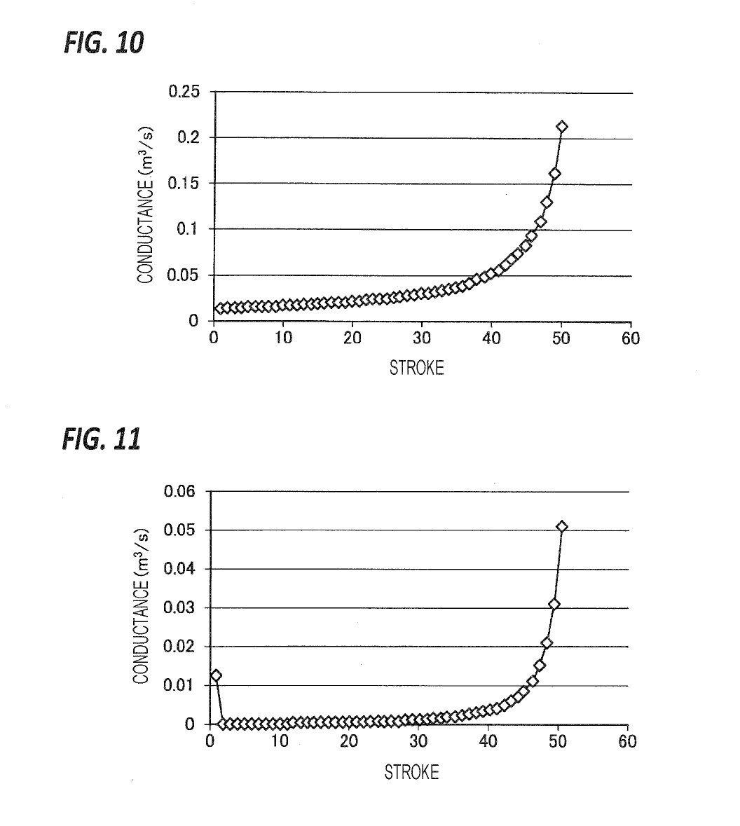

The result of plotting the synthesized conductance C indicated in the aforementioned Equation 5 for each stroke of the shutter 62 is as illustrated in FIG. 10, for example. FIG. 10 is a view illustrating an example of a targeted change in conductance. As apparent from FIG. 10, the change amount in synthesized conductance C with respect to the stroke s is small in the range in which the value of the stroke s is small, and the change amount in synthesized conductance C with respect to the stroke s is large in the range in which the value of the stroke s is large. When the synthesized conductance of the baffle structure 60 is changed as illustrated in FIG. 10 as the stroke s of the shutter 62 is controlled, the pressure in the first space S1 may be changed as illustrated in FIG. 9.

In the present Example, when the shutter 62 is positioned at the position of the stroke s, the through holes 61h, which are disposed between the region 61r corresponding to the stroke having a value of 1 and the region 61r corresponding to the stroke having a value of s, are not covered by the shutter 62. Assuming that the synthesized conductance of the through holes 61h disposed in one region 61r corresponding to the stroke s of the shutter 62 is C(s), the aforementioned Equation 5 may be expressed as follows, for example.

$$\begin{matrix}[ Equation 6 ] & \\ {\int }_{2}^{s} C ( s ) ds = C = \frac{Q}{P ( s )} & ( 6 )\end{matrix}$$

In the present Example, when the value of the stroke s of the shutter 62 is 1, the shutter 62 is positioned at the uppermost side, and only the through holes 61h at the uppermost stage of the first cylindrical portion 61a are not covered by the second cylindrical portion 62a of the shutter 62. Further, when the value of the stroke s is 1, the synthesized conductance of the baffle structure 60 is set as conductance for achieving predetermined pressure as an initial value. Further, the number of through holes 61h or the sizes of openings of the through holes 61h at the uppermost stage of the first cylindrical portion 61a are determined in order to realize the conductance set as the initial value.

The result of plotting, based on the aforementioned Equation 6, the synthesized conductance C(s) of the through holes 61h disposed in the respective regions 61r of the first cylindrical portion 61a for each stroke s is as illustrated in FIG. 11, for example. FIG. 11 is a view illustrating an example of the synthesized conductance C(s) of the through holes 61h in the region 61r corresponding to each stroke s. As apparent from FIG. 11, the change amount in synthesized conductance C(s) of the through holes 61h in the region 61r corresponding to the stroke s is small in the range in which the value of the stroke s is small, and the change amount in synthesized conductance C(s) of the through holes 61h in the region 61r corresponding to the stroke s is large in the range in which the value of the stroke s is large.

Assuming that the conductance of the respective through holes 61h is Cₕ and the number of through holes 61h in the region 61r corresponding to the stroke s is n(s) for each stroke s having a value of 2 or more, the synthesized conductance C(s) of the through holes 61h in the region 61r corresponding to the stroke s is expressed as follows.

[Equation 7]

C(s)=Cₕ×n(s) (7)

Here, in the present Example, each of the through holes 61h has an approximately cylindrical shape. For this reason, the conductance Cₕ of each of the through holes 61h is synthesized conductance of conductance Cₒ of an orifice and conductance C_{L} of a circular conduit.

Here, assuming that a ratio between the conductance Cₕ of each of the through holes 61h and the mass flow rate Q of the gas is C_{Q} (=Cₕ/Q), the number n(s) of through holes 61h in the region 61r corresponding to the stroke s for each stroke s may be determined as follows.

$$\begin{matrix}[ Equation 8 ] & \\ n ( s ) = \frac{α {C}_{q}}{{( {C}_{q} β - {C}_{q} α s )}^{2}} & ( 8 )\end{matrix}$$

In a case in which the value of n(s) calculated based on the aforementioned Equation 8 is not an integer, the value of n(s) is changed to an integer value by rounding off, up, or down the value to the nearest integer to remove a value below a decimal point.

As the through holes 61h of which the number calculated based on Equation 8 is n(s) are disposed in the first cylindrical portion 61a of the baffle plate 61, the synthesized conductance of the baffle structure 60 is changed with respect to the change in stroke of the shutter 62, as illustrated in FIG. 10, for example. That is, the through holes 61h are disposed in the first cylindrical portion 61a of the baffle plate 61 so that the number of through holes 61h in the region 61r corresponding to each stroke s is equal to the number n(s) calculated based on Equation 8 such that the plurality of through holes 61h are disposed in the first cylindrical portion 61a of the baffle plate 61 so that the change amount in synthesized conductance of the through holes 61h, which are not covered by the second cylindrical portion 62a, is increased with respect to the movement amount of the shutter 62 as the shutter 62 is moved downward.

[Simulation Result]

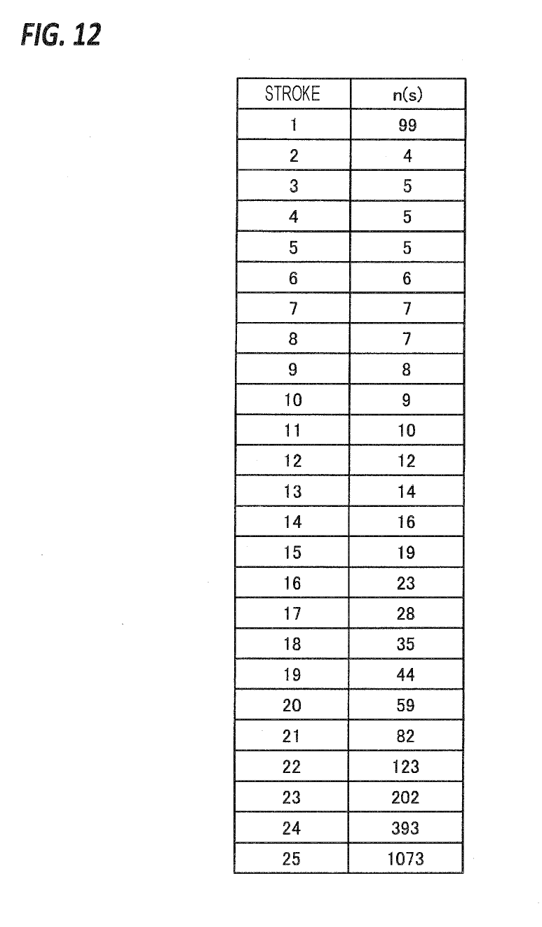

FIG. 12 is a view illustrating an example of an arrangement of the through holes 61h according to Example 1. FIG. 12 illustrates a result of calculating the number n(s) of through holes 61h in the region 61r corresponding to each stroke s using the aforementioned Equation 8 and the following values of parameters. Further, for example, N₂ gas is considered as gas supplied into the processing container 12.

Mass flow rate Q=0.845 Pam³/s

Radius of opening of through hole 61h a=1 mm

Average velocity v=470.4 m/s

Thickness of first cylindrical portion 61a L=5 mm

Maximum value of stroke Sₘₐₓ=25

Maximum value of pressure Pₘₐₓ=66.67 Pa (500 mT)

Minimum value of pressure Pₘᵢₙ=4 Pa (30 mT)

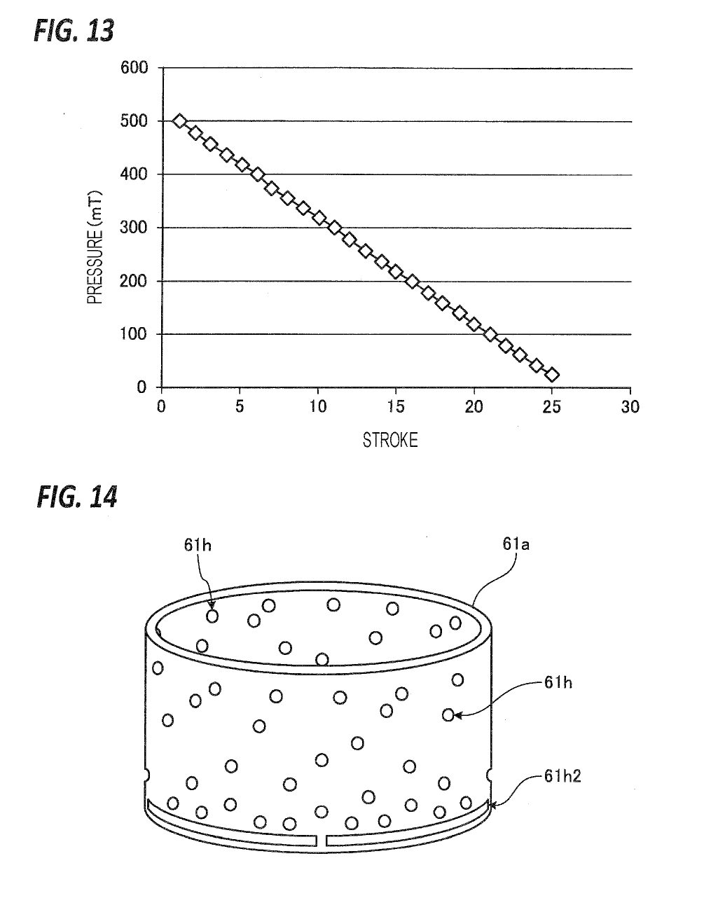

Simulation was performed on the change in pressure in the first space S1 using the baffle plate 61 in which the through holes 61h of which the number is the number n(s) illustrated in FIG. 12 are disposed in the region 61r corresponding to each stroke s. FIG. 13 is a view illustrating an example of a simulation result of pressure control according to Example 1. In FIG. 13, the vertical axis indicates the pressure in the first space S1, and the horizontal axis indicates the stroke s of the shutter 62. As apparent from FIG. 13, the pressure in the first space S1 is linearly changed with respect to the change amount in stroke s of the shutter 62. Therefore, the plasma processing apparatus 10 of the present Example may precisely set the pressure in the first space S1 to any pressure by controlling the stroke s of the shutter 62 within a control range from the maximum value Pₘₐₓ of the pressure to the minimum value Pₘᵢₙ of the pressure. Therefore, the plasma processing apparatus 10 of the present Example may improve controllability of pressure when controlling the pressure in the first space S1 by moving the shutter 62.

In the present Example, the areas of the openings of the respective through holes 61h formed in the first cylindrical portion 61a of the baffle plate 61 are approximately equal to one another. For this reason, the plurality of through holes 61h are disposed in the region 61r of the baffle plate 61 corresponding to a position of the shutter 62 at which the value of the stroke s is large. As the number of through holes 61h formed in the baffle plate 61 is increased, manufacturing costs of the baffle plate 61 are increased, or a length of a sum of diameters of the through holes 61h formed in the respective regions 61r exceeds a circumferential length of the first cylindrical portion 61a in some instances. For this reason, in the region 61r in which the number of through holes 61h is large, several through holes 61h, which are integrated into a single through holes 61h2, may be formed in the first cylindrical portion 61a, as illustrated in FIG. 14, for example. However, in this case, a value of conductance of the through hole 61h2 may be approximately equal to a value of synthesized conductance of the respective through holes 61h integrated into the through hole 61h2. FIG. 14 is a view illustrating another example of an arrangement of the through holes 61h formed in the first cylindrical portion 61a of the baffle plate 61.

Example 1 has been described above. As apparent from the aforementioned description, the plasma processing apparatus 10 of the present example may improve controllability of the pressure in the first space S1.

### EXAMPLE 2

Next, Example 2 will be described. In the plasma processing apparatus 10 according to Example 2, the through holes 61h are formed in the first cylindrical portion 61a of the baffle plate 61 so that the areas of the openings of the through holes 61h in the region 61r corresponding to the stroke s are increased as the value of the stroke s is increased. Further, because the configuration of the plasma processing apparatus 10 except for the first cylindrical portion 61a is identical to that of the plasma processing apparatus 10 according to Example 1, which has been described with respect to FIGS. 1 to 4, except for the following description, a detailed description thereof will be omitted.

[Arrangement of Through Holes 61h]

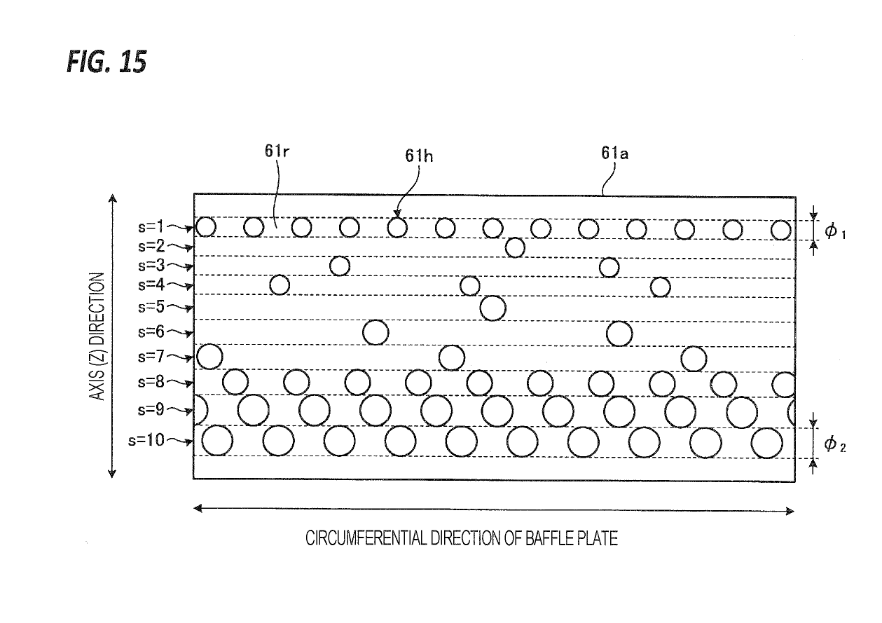

FIG. 15 is a view illustrating an example of an arrangement of the through holes 61h formed in the first cylindrical portion 61a of the baffle plate 61 according to Example 2. For example, as illustrated in FIG. 15, in the first cylindrical portion 61a of the baffle plate 61 according to the present Example, the areas of the openings of the through holes 61h disposed in the respective regions 61r are increased as the value of the stroke s of the shutter 62 is increased, that is, toward the lower side of the first cylindrical portion 61a. In the present Example, since the shape of each of the openings of the through holes 61h has an approximately circular shape, a radius a of the through hole 61h disposed in each of the regions 61r is increased toward the lower side of the first cylindrical portion 61a in the present Example. For example, in the first cylindrical portion 61a illustrated in FIG. 15, a diameter φ2 of the through hole 61h disposed in the region 61r corresponding to the stroke s having a value of 10 is larger than a diameter φ1 of through hole 61h disposed in the region 61r corresponding to the stroke s having a value of 1.

Even in the present Example, the plurality of through holes 61h are disposed in the first cylindrical portion 61a of the baffle plate 61 so that the change amount in synthesized conductance of the through holes 61h, which are not covered by the second cylindrical portion 62a, is increased with respect to the movement amount of the shutter 62 as the shutter 62 is moved downward.

Here, in the case in which the areas of the openings of the respective through holes 61h are equal to one another, the number of through holes 61h in the region 61r corresponding to the position of the shutter 62 at which the value of the stroke is large is larger than the number of through holes 61h in the region 61r corresponding to the position of the shutter 62 at which the value of the stroke is small. Manufacturing costs of the baffle plate 61 are increased as the number of through holes 61h formed in the first cylindrical portion 61a of the baffle plate 61 is increased. Therefore, in the present Example, the number of through holes 61h formed in the first cylindrical portion 61a is reduced by increasing the areas of the openings of the through holes 61h in the region 61r corresponding to the stroke having a large value. Therefore, it is possible to improve controllability of pressure and inhibit an increase in costs of the plasma processing apparatus 10.

[Evaluation Result]

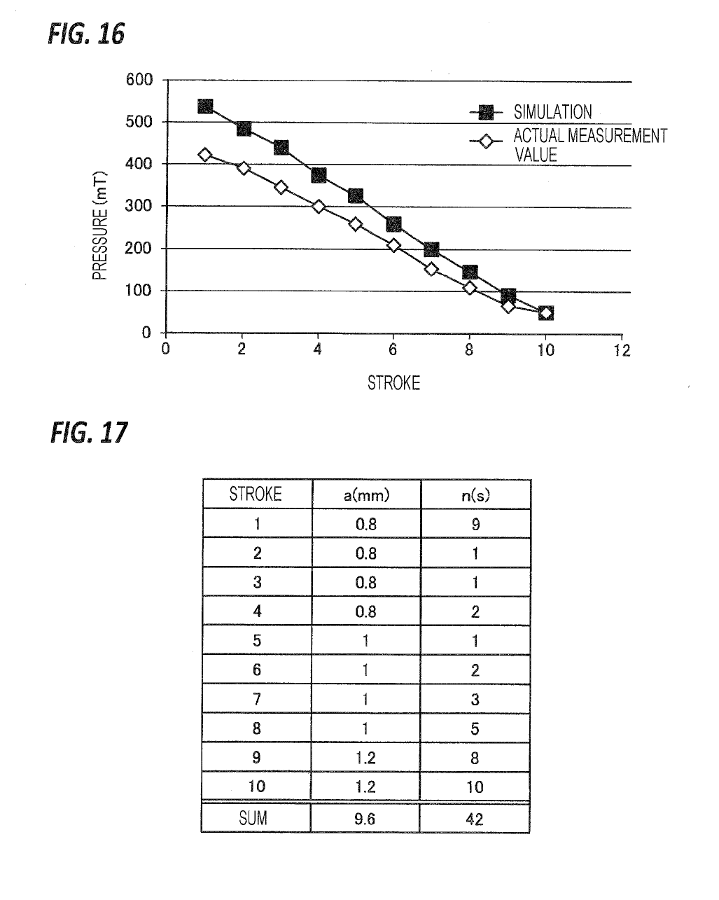

FIG. 16 is a view illustrating an example of an evaluation result of pressure control according to Example 2. In the evaluation result illustrated in FIG. 16, for example, the baffle plate 61, which has the through holes 61h disposed in the region 61r corresponding to each stroke so that the radius a and the number n(s) illustrated in FIG. 17 are made, is used. As indicated by the actual measurement values in FIG. 16, in the plasma processing apparatus 10 of the present Example, the pressure in the first space S1 is changed rectilinearly in accordance with an increase in stroke of the shutter 62. Therefore, even in the plasma processing apparatus 10 of the present Example, it is possible to realize high controllability related to the pressure control. Further, in the data illustrated in FIG. 16, there are differences between the actual measurement values and the simulation values, but the reason is that a value of the gap GP set in the simulation is different from a value of the gap GP in an actual apparatus.

Example 2 has been described above. As apparent from the aforementioned description, the plasma processing apparatus 10 of the present Example may improve controllability of the pressure in the first space S1. Further, according to the plasma processing apparatus 10 of the present Example, it is possible to inhibit an increase in costs of the plasma processing apparatus 10.

[Others]

The disclosed technology is not limited to the aforementioned Examples and may be variously modified within the subject matter thereof.

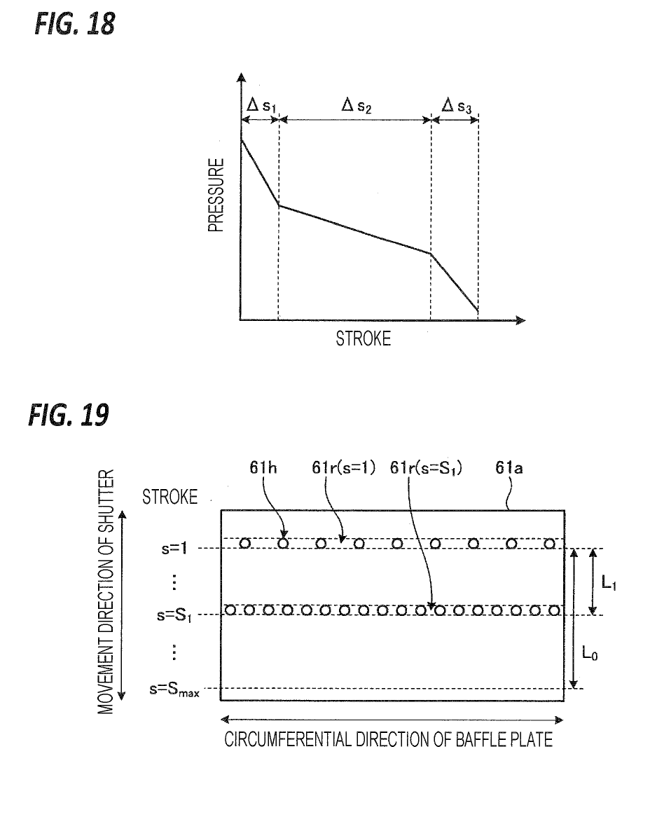

For example, in the respective Examples, the change in pressure in the first space S1 with respect to the change in stroke of the shutter 62 is controlled to be changed along the single straight line, but the disclosed technology is not limited thereto. For example, as illustrated in FIG. 18, the range of the stroke from 1 to the maximum value is divided into a plurality of small ranges Δs₁ to Δs₃, and the through holes 61h may be disposed in the respective regions 61r of the baffle plate 61 so that the pressure in the first space S1 is changed along straight lines having different inclinations for each small range. In this case, the number n(s) of through holes 61h included in the region 61r corresponding to each stroke s in the small region is determined for each small region using a targeted inclination of a change in pressure in the first space S1 and using the aforementioned Equation 8. Further, in the example in FIG. 18, the range of the stroke from 1 to the maximum value is divided into the three small ranges Δs₁ to Δs₃, but the number of divided small ranges is not limited to three, and the number of divided small ranges may be two, or four or more.

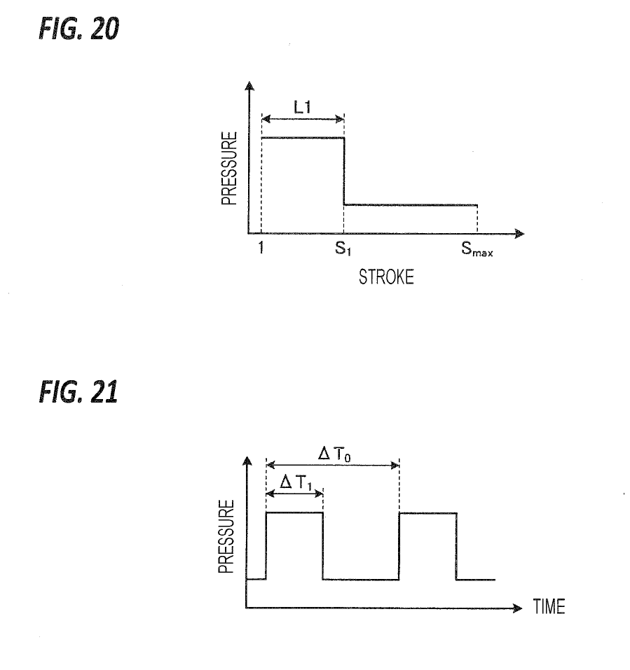

For example, as illustrated in FIG. 19, in the first cylindrical portion 61a of the baffle plate 61, the through holes 61h may be disposed, for example, only in the region 61r corresponding to the stroke having a value of 1 and the region 61r corresponding to the stroke having a value of s₁. In this case, the conductance of the baffle structure 60 is rapidly increased when the shutter 62 is moved downward and the stroke reaches s₁. Therefore, for example, as illustrated in FIG. 20, the pressure in the first space S1 may be rapidly changed based on the position of the shutter 62 at which the value of the stroke is s₁.

For example, as illustrated in FIG. 21, the pressure in the first space S1 may be alternately changed in a pulse shape by, for example, reciprocally moving the stroke of the shutter 62 at a constant speed within a range of 1 to sₘₐₓ using the first cylindrical portion 61a illustrated in FIG. 19. Assuming that in the change in pressure in a pulse shape illustrated in FIG. 21, a ratio of a period of time ΔT₁ of high pressure to a period of time ΔT₀ of 1 cycle is defined as a duty ratio, the duty ratio corresponds to a ratio of a distance L₁ to a distance L₀ illustrated in FIG. 19. The distance L₀ illustrated in FIG. 19 is a distance from a lower end of the region 61r corresponding to the stroke s having a value of 1 to a lower end of the region 61r corresponding to the stroke s having a value of sₘₐₓ. In addition, the distance L₁ illustrated in FIG. 19 is a distance from a lower end of the region 61r corresponding to the stroke s having a value of 1 to a lower end of the region 61r corresponding to the stroke s having a value of s₁.

The pulse control of pressure with any duty ratio may also be implemented by controlling the driving device 70 so as to change the stroke s of the shutter 62 from s_{i-1 to s}₁ at a predetermined timing and change the stroke s of the shutter 62 from s₁ to s₁-1 at a predetermined timing.

A width of each of the regions 61r in the direction of the axis Z is approximately equal to a diameter of the through hole 61h disposed in the region 61r. For this reason, in Example 2, in a case in which the number of regions 61r including the through holes 61h having a large radius is excessively increased, a movement range of the shutter 62 is increased, and it is difficult to reduce a size of the plasma processing apparatus 10. Therefore, in a case in which a length of a sum of widths of all of the regions 61r in the direction of the axis Z exceeds a predetermined length, the through holes 61h may be substituted with the through holes 61h having a small radius in the order from the region 61r in which the number n(s) of through holes 61h is small until the length of the sum of the widths of all of the regions 61r in the direction of the axis Z becomes smaller than the predetermined length. Therefore, it is possible to inhibit an increase in costs of the plasma processing apparatus 10 within a range in which the size of the plasma processing apparatus 10 may be reduced.

### DESCRIPTION OF SYMBOLS

W: Wafer

10: Plasma processing apparatus

12: Processing container

14: Placement table

20: Electrostatic chuck

30: Upper electrode

34: Electrode plate

36: Electrode support body

48: Gas discharge pipe

50: Gas discharge device

60: Baffle structure

61: Baffle plate

61h: Through hole

62: Shutter

70: Driving device

What is claimed is:

1. A plasma processing apparatus that performs plasma processing on a workpiece, the plasma processing apparatus comprising:
a processing container;
a placement table provided in the processing container and configure to place the workpiece thereon;
a cylindrical baffle plate having a plurality of through holes formed in a sidewall thereof, and defining a processing space above the placement table and a gas discharge space around the placement table;
a cylindrical shutter having an inner circumferential surface having a diameter larger than a diameter of an outer circumferential surface of the baffle plate, is the shutter being provided around the baffle plate to be movable in an axial direction of the baffle plate along the sidewall of the baffle plate; and
a driving device configured to change synthesized conductance made by the plurality of through holes, which are not covered by the shutter, by moving the shutter along the sidewall of the baffle plate,
wherein the plurality of through holes are disposed in the sidewall of the baffle plate such that a change amount of the synthesized conductance of the through holes, which are not covered by the shutter, is increased with respect to a movement amount of the shutter as the shutter is moved downward.

2. The plasma processing apparatus of claim 1, wherein assuming that, for each of regions of the sidewall of the baffle plate through which an upper end of the shutter passes when the position of the shutter is changed by a predetermined distance, a number, which is assigned in the ascending order to the regions in an order that the upper end of the shutter passes when the shutter is moved downward, is defined as s, conductance of each of the through holes is defined as Cₕ, an inclination of a straight line indicating a change in pressure in the processing container with respect to a targeted movement amount of the shutter is defined as −α, a segment of the straight line is defined as β, and a mass flow rate of gas supplied into the processing space is defined as Q, the number n(s) of the through holes disposed in the region indicated by the number s satisfies Equation 1 as follows.
$$\frac{α {C}_{q}}{{( {C}_{q} β - {C}_{q} α s )}^{2}} = n ( s ) \\ {C}_{q} = \frac{{C}_{h}}{Q} \qquad [ Equation 1 ]$$

3. The plasma processing apparatus of claim 2, wherein the through holes, which are disposed in the regions, respectively, are disposed in the regions such that intervals between adjacent through holes in the regions are uniform.

4. The plasma processing apparatus of claim 2, wherein an opening area of each of the through holes disposed in the region to which the number s having a large value is assigned is larger than an opening area of each of the through holes disposed in the region to which the number s having a small value is assigned.

5. The plasma processing apparatus of claim 1, wherein each of the through holes is disposed in the sidewall of the baffle plate such that each of the through holes less overlap other through holes in the axial direction of the baffle plate.
